(19) United States
(12) Patent Application Publication
(10) Pub. No.: US 2024/0088202 A1
(43) Pub. Date: Mar. 14, 2024

(54) MATERIAL DEPOSITION METHOD AND MICROSYSTEM THEREWITH OBTAINED

(71) Applicant: LUXEMBOURG INSTITUTE OF SCIENCE AND TECHNOLOGY (LIST), Eschsur-Alzette (LU)

(72) Inventors: Naveen ARUCHAMY, Esch-sur-Alzette (LU); Torsten GRANZOW, Esch-sur-Alzette (LU); Emmanuel DEFAY, Esch-sur-Alzette (LU); Sebastjan GLINSEK, Esch-sur-Alzette (LU)

(21) Appl. No.: 18/272,513

(22) PCT Filed: Jan. 13, 2022
(86) PCT No.: PCT/EP2022/050664

§ 371 Date: Jul. 14, 2023

(30) Foreign Application Priority Data
Jan. 15, 2021 (LU) LU102421

(51) Int. Cl. H10N 30/093; H10N 30/067

(52) U.S. Cl. CPC H01L 28/56; H10N 30/067; H10N 30/093

(57) ABSTRACT

A material deposition method comprising: providing a substrate; forming a film of HfO2 by chemical solution deposition, CSD, on the substrate; depositing a solution of PbTiO3 on the film of HfO2; depositing a layer of Pb(Zrx,Ti1-x)O3 on the seed layer, where O≤x≤1; and forming interdigitated electrodes on the Pb(Zrx,Ti1-x)O 3 layer. Also a ferroelectric microsystem obtained by this deposition method. Experiments show an improved fatigue resistance for such a microsystem.

### CROSS-REFERENCE TO RELATED APPLICATIONS

The present invention is the US national stage under 35 U.S.C. § 371 of International Application No. PCT/EP2022/050664 which was filed on Jan. 13, 2022, and which claims the priority of application LU102421 filed on Jan. 15, 2021 the contents of which (text, drawings and claims) are incorporated here by reference in its entirety.

### FIELD

The invention relates to the field of microsystem manufacturing and especially the manufacturing of electroactive (pyroelectric or piezoelectric or ferroelectric or antiferroelectric or electrostrictive or dielectric) devices obtained by deposition of components on a substrate.

In particular, the invention relates to ferroelectric field-effect transistors.

### BACKGROUND

Ferroelectric capacitors on silicon substrate are generally manufactured as a MIM structure: a Metallic bottom electrode, an Insulating layer, and a Metallic top electrode.

The material of the bottom electrode (Pt or AgPd) must be selected to withstand the high temperatures induced by the deposition process of the insulating layer.

The insulating layer can be a Pb(ZrₓTi₁₋ₓ)O₃ film (PZT).

To ensure that such capacitors maintain their properties in the long run (endurance to fatigue), conductive oxide electrodes can be used instead of metallic electrodes. These electrodes have a lower conductivity in comparison to metallic electrodes and they limit the frequency range usable for switching such capacitors.

Therefore, the choice for the material used for the bottom electrode is very restricted.

A different known structure is constituted of planar electrodes (PE). This structure is usually not used for switching devices. However, PE structures do not have the constraint of an electrode material that requires to withstand high temperatures.

To envisage using a PE structure for a switching application, one needs to ensure that the PE structure can support several millions of cycles.

Literature does not provide any technical solution to ensure this property for PE structures.

PE structures used for switching device further require to insulate electrically and chemically any conductive substrate from the PZT film.

There are therefore technological gaps preventing the use of PE for a switching device.

### SUMMARY

The present invention addresses the above-mentioned deficiencies and aims at filling the above-mentioned technological gap, providing a ferroelectric system and manufacturing method, wherein the system has a PE structure and can be reliably used for switching applications thanks to its higher fatigue resistance.

The above-stated problem is solved by a material deposition method comprising: providing a substrate; forming a film of HfO₂ by chemical solution deposition on the substrate; depositing a seed layer of a solution of PbTiO₃ on the film of HfO₂; depositing a layer of Pb(Zrₓ,Ti₁₋ₓ)O₃ on the seed layer, where 0≤x≤1; and forming interdigitated electrodes on the Pb(Zrₓ,Ti₁₋ₓ)O₃ layer.

As will be explained in more details below, the inventors have shown that the use of a layer of HfO₂ deposited as a solution (chemical solution deposition, CSD) improves the fatigue resistance of a microsystem with planar electrodes. The combination of the columnar microstructure of CSD and the planar electrode creates a synergy that shows to be beneficial to the fatigue resistance.

The microsystem has similar ferroelectric use as a MIM structured microsystem but has economical advantage (manufacturing method and liberty to choose among a wider range of material).

According to an exemplary embodiment, the film of HfO₂ is formed by deposition of at least two layers, each layer having a thickness of about 15 nm and deposited by spin coating. According to an exemplary embodiment, the spin coating operation is performed at a speed comprised between 2000 rpm and 4000 rpm, in various instances at 3000 rpm, and for a duration comprised between 20 and 40 seconds, for example during 30 seconds. These parameters enable a good fatigue resistance, a good adhesion of the HfO₂ layer on the substrate and no negative effect on the crystallographic (1 0 0) orientation of PZT.

According to an exemplary embodiment, after each layer is formed, an operation of drying at 215° C. for 5 min is carried out.

According to an exemplary embodiment, after its deposition, the film of HfO₂ is annealed in a furnace at 700° C. for 90 s.

According to an exemplary embodiment, the chemical solution of HfO₂ is a solution of 0.25 M Hf-Acetylacetonate in propionic acid.

According to an exemplary embodiment, the seed layer is deposited by spin coating a precursor solution of PbTiO₃ prepared using 2 methoxy-ethanol or 1-methoxy-2-propanol as a solvent and optionally acetylacetone as a modifier.

According to an exemplary embodiment, x=0.53, hence Pb(Zrₓ,Ti₁₋ₓ)O₃ is Pb(Zr_{0.53},Ti_{0.47})O₃.

According to an exemplary embodiment, the substrate is a fused silica substrate.

According to an exemplary embodiment, the substrate is a silicon substrate with interlayers of SiO₂.

According to an exemplary embodiment, the substrate is a sapphire substrate. Sapphire tends to generate lower compressive stress on the PZT film which enables to build a thicker PZT film as the risk of cracks is reduced.

Sapphire is also more stable and has a lower conduction, rendering it more suitable for non-FET based FE-RAM.

The invention also relates to a microsystem obtained at least partly by the above-mentioned method. As exemplified below, analyses have shown that the microsystem is physically distinct from a microsystem obtained with other materials or other deposition methods.

The layer of HfO₂ also makes the thickness of the microsystem and its capacitance greater, which for some particular applications can be advantageous (e.g., micro-capacitor for electrical energy storage, radio-frequency tuning, etc.).

The seed layer improves the preferential (1 0 0) orientation of the PZT.

### DRAWINGS

FIG. 1 is an exemplary cross-section of a microsystem device in accordance with various embodiments of the invention.

FIGS. 2 and 3 exemplarily show a comparison of fatigue experiments between a known device and the device of the invention in accordance with various embodiments of the invention.

### DETAILED DESCRIPTION

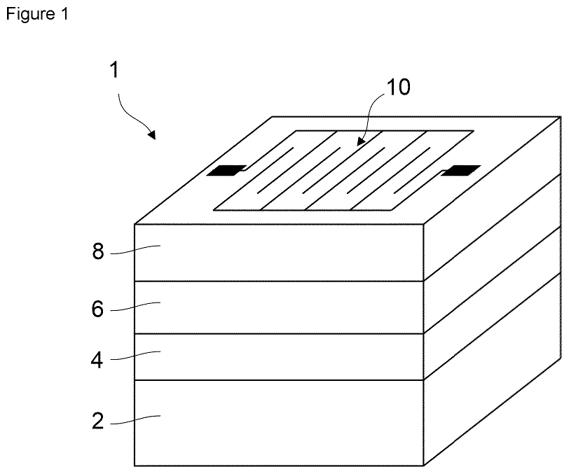

FIG. 1 shows a cross-section (not to scale) of a microsystem 1. The microsystem 1 comprises a superposition of films on a substrate 2.

A HfO₂ film 4 is deposited (directly) on the substrate 2. A PbTiO₃ seed layer 6 is (directly) deposited on the HfO₂ film 4. A PZT layer 8 is built on the seed layer 6. Electrodes 10 are formed on the PZT layer 8. None of the layers 2, 4, 6, 8 contains or is interposed with an electrode.

The substrate 2 can be a 500 nm thick Si wafer from Siegert Wafer GmbH.

The HfO₂ passivation film can be made of at least two layers deposited by CSD using 0.25 M HfO₂ solution (Hf-acetylacetonate in propionic acid). The substrate 2 can be heated at 350° C. on a hot plate for surface activation. Then the HfO₂ solution can be spin coated at 3000 rpm for 30 seconds, followed by drying at 215° C. for 5 minutes. The operation can be repeated at least once to obtain a thickness of HfO₂ film of 30 nm. Then the film can be annealed in a rapid thermal annealing furnace at 700° C. for 90 seconds.

The PbTiO₃ (PT) seed layer 6 can be prepared as discussed extensively in Luxembourgish patent application LU101884, i.e., with 2 methoxy-ethanol or 1-methoxy-2-propanol as solvent and optionally acetylacetone as modifier.

A film of PZT can be deposited over the seed layer 6, in various instances preferably Pb(Zr_{0.53},Ti_{0.47})O₃. The PZT film is deposited on the seed layer by spin-coating. Alternatively, the deposition can be made by inkjet printing, sputtering, Pulsed Laser Deposition, MOCVD, etc. Again, patent application LU101884 provides exemplary details of the preparation and deposition of the PZT film.

Lead(II) acetate trihydrate (99.5%, Sigma-Aldrich, USA), titanium (IV)-isopropoxide (97%, Sigma-Aldrich, USA) and zirconium (IV)-propoxide (70% in propanol, Sigma-Aldrich, USA) can be used as precursors in stoichiometric ratio with 2-methoxyethanol as solvent to prepare both the PT and PZT solution. The PT solution can be spin-coated onto the HfO₂ layer at 3000 rpm for 30 s, followed by drying and pyrolysis at 130° C. and 350° C., respectively, on hot plates. Final crystallization can be performed at 700° C. for 60 s in a rapid thermal annealing furnace (AS—Master, Annealsys, France) at 50° C./s heating rate in air. The PZT solution is then spin-coated, dried and pyrolyzed following the same deposition steps. After a couple of (e.g., four) subsequent deposition-drying-pyrolysis cycles, crystallization can happen at 700° C. in air for 300 s at 50° C./s heating rate, resulting in −170 nm thick PZT films. The aforementioned steps for PZT deposition can be repeated three times to achieve 500 nm film thickness. This process can also be adapted to fabricate thicker layers of PZT up to 1.2 μm.

Over the PZT layer are formed planar electrodes. In particular, interdigitated electrodes (IDE) can be formed, having fingers of 10 μm of width and an inter-finger distance of about 10 μm. IDEs are patterned by lift-off photolithography using a direct laser writing (MLA, Heidelberg Instruments). Platinum electrodes of 100 nm can then be DC-sputtered at room temperature. The IDE geometry is only schematically illustrated in FIG. 1. The exact geometry of the design (width of individual fingers, width of gap between fingers, number of fingers, size of contact pads at each end) will be chosen according to the intended application of the microsystem (in particular depending on the required cycling speed).

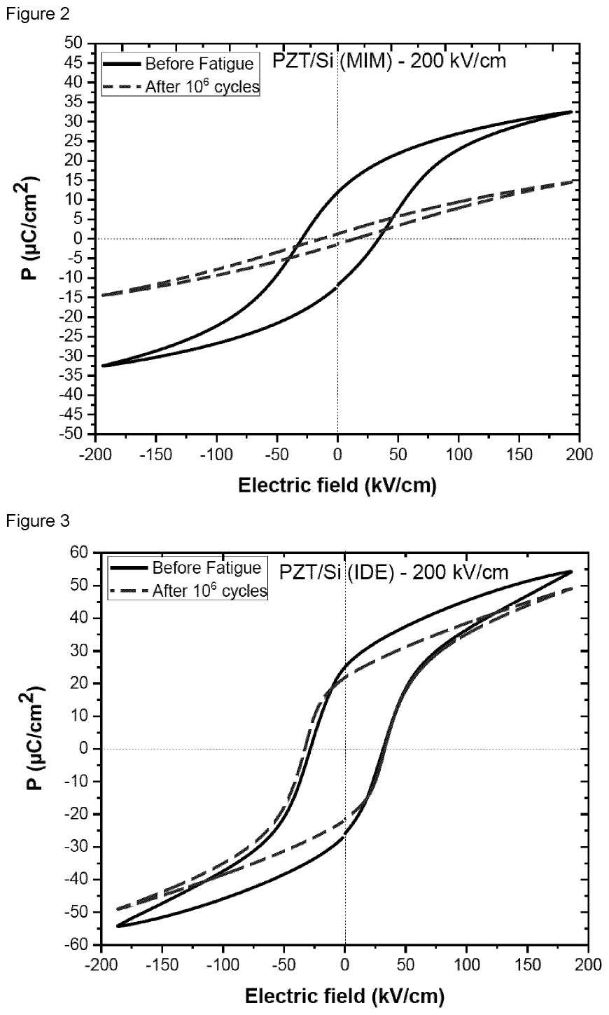

The microsystem of the invention constitutes a substantial improvement over the known systems. FIGS. 2 and 3 highlight this improvement. A cyclically varying external electric field was applied to the capacitor structure to change the electrical polarization. In the present example, a frequency of 100 Hz at field amplitudes of 150 kV/mm and 200 kV/mm, respectively, was applied. Further experiments confirm that an amplitude which is sufficient to induce polarization switching leads to the same conclusions (i.e., an amplitude equal to or greater than 75 kV/cm).

FIG. 2 shows the development of the ferroelectric polarization loops measured on the known MIM structure in a new condition and after 1 million cycles (dotted line).

FIG. 3 shows a similar chart for the IDE structure with HfO₂ (CSD) layer according to the invention.

Both FIGS. 2 and 3 show comparable hysteresis properties during the first few cycles, indicating that the performance of the device with the IDE structure can compete with the performance of the conventional MIM structure.

After one million cycles, the MIM structure shows notable degradation. The most important parameter for ferroelectric applications, the remnant polarization at zero field, nearly vanishes in the system having the MIM structure. In contrast, the shape of the polarization hysteresis of the IDE structure (FIG. 3, dotted line) is only slightly affected by the million cycles, the device conserving substantially the same remnant polarization. Any device based on the capacitor with the MIM structure is therefore unusable after 10⁶ switching cycles, whereas a device based on the capacitor with the IDE structure and HfO₂ (CSD) layer remains functional.

The results of FIGS. 2 and 3 are consistent throughout the various solicitation (frequency, amplitude and number of cycles). Also, the improvement in fatigue is independent from the presence of the PbTiO₃ seed layer.

HfO₂ deposited by another technology (e.g., atomic layer deposition) does not result in the same fatigue improvement.

It is therefore concluded that the deposition of HfO₂ by CSD technique is responsible of the improvement of the IDE-made microsystem fatigue resistance.

The exemplary embodiments presented above and the various quantities and numbers are given to illustrate the invention. The person skilled in the art would understand that the scope of the invention is only limited by the appended claims and that variations in the amount of dilution, the temperatures or the time duration for the various steps of the method do not depart from the scope of the present invention. For example, variations of about 10% to 20% in the dilution ratios, the duration of the steps, the temperatures or the speed of the spinner can be used.

If the particular application cited above relates to ferroelectric field-effect transistors, the invention also provides advantages in other applications, such as non-volatile RAM, memories with pyroelectric readout, piezoelectric applications using electrical cycling under high-amplitude electric fields.

1-12. (canceled)

13. A material deposition method, said method comprising:
providing a substrate;
forming a film of HfO₂ by chemical solution deposition on the substrate;
depositing a seed layer of a solution of PbTiO₃ on the film of HfO₂;
depositing a layer of Pb(Zrₓ,Ti₁₋ₓ)O₃ on the seed layer, where 0≤x≤1; and
forming interdigitated electrodes on the Pb(Zrₓ,Ti₁₋ₓ)O₃ layer.

14. The method according to claim 13, wherein the film of HfO₂ is formed by deposition of at least two layers, each layer having a thickness of about 15 nm and deposited by spin coating.

15. The method according to claim 14, wherein the spin coating operation is performed at a speed comprised between 2000 rpm and 4000 rpm, and for a duration comprised between 20 and 40 seconds.

16. The method according to claim 14, wherein the spin coating operation is performed at 3000 rpm, and for a duration of 30 seconds.

17. The method according to claim 14, wherein after each layer is formed, an operation of drying at 215° C. for 5 min is carried out.

18. The method according to claim 13, wherein after its deposition, the film of HfO₂ is annealed in a furnace at 700° C. for 90 s.

19. The method according to claim 13, wherein the chemical solution of HfO₂ is a solution of 0.25 M Hf-Acetylacetonate in propionic acid.

20. The method according to claim 13, wherein the seed layer is deposited by spin coating a precursor solution of PbTiO₃ prepared using 2 methoxy-ethanol or 1-methoxy-2-propanol as a solvent and optionally acetylacetone as a modifier.

21. The method according to claim 13, wherein x=0.53.

22. The method according to claim 13, wherein the substrate is a fused silica substrate.

23. The method according to claim 13, wherein the substrate is a silicon substrate with interlayers of SiO₂.

24. The method according to claim 13, wherein the substrate is a sapphire substrate.
